(19) United States
(12) Patent Application Publication
(10) Pub. No.: US 2005/0157529 A1
(43) Pub. Date: Jul. 21, 2005

(54) Ic card

(76) Inventors: Hiroshi Iwata, Nara (JP); Akihide Shibata, Nara (JP); Kouichirou Adachi, Nara (JP)

Correspondence Address: BIRCH STEWART KOLASCH & BIRCH, PO BOX 747, FALLS CHURCH, VA, 22040-0747, US

(21) Appl. No.: 10/513,959

(22) PCT Filed: May 29, 2003
(86) PCT No.: PCT/JP03/06730

(30) Foreign Application Priority Data
May 31, 2002 (JP) 2002-158645
Apr. 1, 2003 (JP) 2003-97977

(51) Int. Cl. G11C 11/22

(52) U.S. Cl. 365/145

(57) ABSTRACT

An IC card includes a data memory portion (503) having a plurality of storage devices. The data storage devices each has: a semiconductor substrate, a well region provided in a semiconductor substrate, or a semiconductor film disposed on an insulator; a gate insulating film formed on the semiconductor substrate, the well region provided in the semiconductor substrate, or the semiconductor film disposed on the insulator; a single gate electrode formed on the gate insulating film; two memory function parts formed on opposite sides of the single gate electrode; a channel region disposed under the single gate electrode; and diffusion layer regions disposed on both sides of the channel region. Incorporating a memory using the storage devices, which allow further miniaturization, provides an IC card at low cost.

### BACKGROUND OF THE INVENTION

The present invention relates to an IC card. More specifically, the present invention relates to an IC card including storage devices each composed of a field-effect transistor having a function to convert changes of an electric charge amount or polarization to a current amount.

The structure of a prior art IC card is shown in FIG. 24. In the IC card 9, there are incorporated an MPU (Micro Processing Unit) portion 901, a connection portion 902, and a data memory portion 903. In the MPU portion 901, there are provided an operation portion 904, a control portion 905, a ROM (Read Only Memory) 906, and a RAM (Random Access Memory) 907, each of which is formed upon one chip. The above-stated portions are connected to each other via a line 908 (including a data bus and a power supply line). The connection portion 902 and an external reader/writer 909 are connected when the IC card 9 is attached to the reader/writer 909, by which power is supplied to the card and data exchange is performed.

The data memory portion 903 is composed of a rewritable memory device, typically composed of EEPROM (Electrically Erasable Programmable ROM). The ROM 906 is typically composed of a mask ROM to mainly store a program for driving MPU.

The IC card is usable in extremely large variety of applications such as cash cards, credit cards, ID cards, and prepaid cards. However, for more widespread use of the IC card, one of the key points is to achieve further cost reduction. Cost reduction of a memory portion among components constituting the IC card is an important target to achieve.

### SUMMARY OF THE INVENTION

In view of the above target, it is an object of the present invention to provide a low-cost IC card by incorporating a memory using storage devices capable of achieving further miniaturization.

In order to accomplish the above object, there is provided, according to the present invention, an IC card comprising:
a data memory portion having a plurality of storage devices, said data storage devices each comprising:
a semiconductor substrate, a well region provided in a semiconductor substrate, or a semiconductor film disposed on an insulator;
a gate insulating film formed on the semiconductor substrate, the well region provided in the semiconductor substrate, or the semiconductor film disposed on the insulator;
a single gate electrode formed on the gate insulating film;
two memory function parts formed on opposite sides of the single gate electrode;
a channel region disposed under the single gate electrode; and
diffusion layer regions disposed on both sides of the channel region, wherein
the storage devices are each structured so as to change a current amount flowing from one of the diffusion layer regions to the other of the diffusion layer regions when voltage is applied to the gate electrode, by an amount of electric charges stored in the memory function parts or by polarization vector.

According to the above-constituted IC card, the storage devices incorporated in the data memory portion are each structured such that memory function parts are formed on both sides of the gate electrode, independently of the gate insulating film. Consequently, since each of the memory function parts is separated by the gate electrode, interference in a rewrite operation can be effectively restrained. Also, since a memory function implemented by the memory function parts and a transistor operation function implemented by the gate insulating film are independent from each other, it becomes possible to make the gate insulating film thinner to thereby control the short channel effect. This facilitates miniaturization of the storage devices.

The above storage devices are easy to miniaturize and therefore it becomes possible to reduce an area of the data memory portion incorporating the plurality of storage devices. This leads to cost reduction of the data memory portion, thereby enabling cost reduction of the IC card including the data memory portion.

In one embodiment, the IC card has a logic portion. This makes it possible to impart not only a storage function but also a variety of functions to the IC card.

In one embodiment, the IC card includes a communication means for communicating with external apparatuses and a collecting means for converting electromagnetic waves applied from the outside to electric power, which eliminates the necessity of providing a terminal for establishing electric connection to external apparatuses. Eventually, it becomes possible to prevent electrostatic destruction through the terminal. Further, since close contact to the external apparatuses is not necessarily necessary, freedom of application configurations becomes large. In addition, the storage devices constituting the data memory portion operate at relatively low supply voltage, which enables downsizing of a circuit of the above collecting means and enables cost reduction.

In one embodiment, the data memory portion and the logic portion are formed in one chip.

In the constitution of the above embodiment, a decreased number of chips incorporated in the IC card reduces costs. Further, since the process for forming the storage devices that constitute the data memory portion is quite close to the process for forming devices that constitute the logic portion, placement of the devices of both types in a mixed or combined manner is particularly easy. Therefore, forming the logic portion and the data memory portion in one chip enables implementation of particularly large cost reducing effect.

In one embodiment, the logic portion includes a storage means for storing a program that defines operation of the logic portion, the storage means is rewritable from outside, and the storage means includes storage devices having a constitution identical to a constitution of the storage devices of the data memory portion.

According to the above embodiment, since the storage means is rewritable from the outside, rewriting the above program according to need will achieve remarkable increase of the functions of the IC card. Since the storage devices are easy to miniaturize, increase of a chip area can be minimized even if, for example, a mask ROM is replaced by the storage device. Further, since the process of forming the storage device is quite close to the process for forming the device that constitutes the logic portion, mixed placement of the both devices is easy so that cost increase can be minimized.

In one embodiment, two-bit information is stored in each of the storage devices.

According to the above embodiment, every storage device is capable of storing two-bit information and a capability thereof is fully implemented. Therefore, compared with the case of storing one-bit information in every device, a device area per bit is reduced by half, so that an area of the data memory portion or the storage device can be further decreased. This leads to further cost reduction of the IC card.

In one embodiment, the memory function parts each have a first insulator, a second insulator, and a third insulator. The memory function parts each have a structure in which a film composed of the first insulator having a function of storing electric charges is interposed between the second insulator and the third insulator. The first insulator is silicon nitride, and the second and third insulators are silicon oxide.

The above arrangement makes it possible to increase the operating speed and reliability of the IC card.

In one embodiment, a thickness of a film composed of the second insulator on the channel region is smaller than a thickness of the gate insulating film and is 0.8 nm or more. Therefore, it is possible to either decrease the power supply voltage for the IC card, or increase the operating speed of the IC card.

In one embodiment, a thickness of a film composed of the second insulator on the channel region is larger than a thickness of the gate insulating film, and is 20 nm or less. This arrangement makes it possible to either increase the storage capacity of the data memory portion to thereby enhance the functions of the IC card, or reduce the production costs.

In one embodiment, the film composed of the first insulator having a function of storing electric charges includes a portion having a surface that is approximately parallel to a surface of the gate insulating film. This improves the reliability of the IC card.

In one embodiment, the film composed of the first insulator having a function of storing electric charges includes a portion extending in a direction approximately parallel to a lateral side of the gate electrode. This arrangement can increase the operating speed of the IC card.

In one embodiment, at least part of each memory function part is formed so as to overlap the corresponding diffusion layer region. This arrangement can increase the operating speed of the IC card.

### BRIEF DESCRIPTION OF THE DRAWINGS

FIG. 1 shows a structure of an IC card according to Embodiment 10 of the present invention;

FIG. 2 is a circuit diagram showing an arrangement of storage devices constituting a part of the IC card of Embodiment 10;

FIG. 3 shows a structure of an IC card according to Embodiment 11 of the present invention;

FIG. 4 shows a structure of an IC card according to Embodiment 12 of the present invention;

FIG. 5 is a schematic cross sectional view showing a main part of a storage device in Embodiment 1 of the present invention;

FIG. 6 is an enlarged schematic cross sectional view showing an essential part of FIG. 5;

FIG. 7 is an enlarged schematic cross sectional view of a variant of the part of FIG. 5;

FIG. 8 is a graph showing electrical characteristics of the storage device in Embodiment 1 of the present invention;

FIG. 9 is a schematic cross sectional view of an essential part of a modification of the storage device in Embodiment of the present invention;

FIG. 10 is a schematic cross sectional view showing an essential part of a storage device in Embodiment 2 of the present invention;

FIG. 11 is a schematic cross sectional view showing an essential part of a storage device in Embodiment 3 of the present invention;

FIG. 12 is a schematic cross sectional view showing an essential part of a storage device in Embodiment 4 of the present invention;

FIG. 13 is a schematic cross sectional view showing an essential part of a storage device in Embodiment 5 of the present invention;

FIG. 14 is a schematic cross sectional view showing an essential part of a storage device in Embodiment 6 of the present invention;

FIG. 15 is a schematic cross sectional view showing an essential part of a storage device in Embodiment 7 of the present invention;

FIG. 16 is an illustration for describing a program operation on a storage device in the present invention;

FIG. 17 is an illustration for describing a program operation on a storage device in the present invention;

FIG. 18 is an illustration for describing a first erase operation on a storage device in the present invention;

FIG. 19 is an illustration for describing a second erase operation on a storage device in the present invention;

FIG. 20 is an illustration for describing a read operation on a storage device in the present invention;

FIG. 21 is a graph showing electrical characteristics of a storage device according to the present invention;

FIG. 22 is a graph showing electrical characteristics of a conventional EEPROM;

FIG. 23 a schematic cross sectional view of a transistor constituting a standard logic; and

FIG. 24 shows a structure of a conventional IC card.

### DETAILED DESCRIPTION OF THE PREFERRED EMBODIMENTS

First, storage devices used in an IC card according to the present invention will be outlined below.

Each of storage devices in the present invention is mainly composed of a gate insulating film, a gate electrode formed on the gate insulating film, memory function parts formed on both sides of the gate electrode, source/drain regions (diffusion layer regions) disposed separately on the side opposite from the gate electrode of the memory function parts, and a channel region disposed under the gate electrode.

The storage device functions as a memory device storing four-valued or more information by storing binary or more information in one memory function part. However, the storage device functions not necessarily to store four-valued or more information, but it may also function to store, for example, binary information.

It is preferable that the storage device of the present invention is formed on a semiconductor substrate, preferably in a first conductivity type well region formed in the semiconductor substrate.

The semiconductor substrate is not limited to particular ones as far as it is applicable to semiconductor apparatuses, and it is possible to use various substrates such as substrates made from elemental semiconductors including silicon and germanium, substrates made from compound semiconductors including GaAs, InGaAs and ZnSe, SOI substrates and multilayer SOI substrates, and substrates having a semiconductor layer on a glass or plastic substrate. Among these, a silicon substrate or an SOI substrate having a silicon layer formed as a surface semiconductor layer is preferable. The semiconductor substrate or the semiconductor layer may be either of a single crystal (e.g., single crystal obtained by epitaxial growth), polycrystalline, or amorphous, though a current amount flowing inside will be slightly different among them.

In the semiconductor substrate or the semiconductor layer, it is preferable that device isolation regions are formed, and it is more preferable to combine elements such as transistors, capacitors and resistors, a circuit composed thereof, a semiconductor device, and an inter-layer insulating film or films to form into a single or a multilayer structure. It is noted that the device isolation region may be formed by any of various device isolation films including a LOCOS (local oxidation of silicon) film, a trench oxide film, and an STI film. The semiconductor substrate may be either of a P type or an N type conductivity type, and it is preferable that at least one first conductivity type (P type or N type) well region is formed in the semiconductor substrate. Acceptable impurity concentrations of the semiconductor substrate and the well region are those within the known range in the art. It is noted that in the case of using an SOI substrate as the semiconductor substrate, a well region may be formed in the surface semiconductor layer, and also a body region may be provided under the channel region.

Examples of the gate insulating film are not particularly limited and include those for use in typical semiconductor apparatuses, such as insulating films including silicon oxide films and silicon nitride films; and high-dielectric films including aluminum oxide films, titanium oxide films, tantalum oxide films, hafnium oxide films, in the form of single-layer films or multi-layer films. Among these, the silicon oxide film is preferable. An appropriate thickness of the gate insulating film is, for example, approx. 1 to 20 nm, preferably 1 to 6 nm. The gate insulating film may be only formed right under the gate electrode, or may be formed to be larger (in width) than the gate electrode.

The gate electrode is formed on the gate insulating film in the form typically used in semiconductor apparatuses. Unless particularly specified in the embodiments, examples of the gate electrode are not particularly limited and therefore include conductive films such as polysilicon; metals including copper and aluminum; high-melting metals including tungsten, titanium, and tantalum; and silicides of high-melting metals, in the form of a single-layer or a multi-layer. An appropriate film thickness of the gate electrode is approx. 50 to 400 nm. The channel region, which is below the gate electrode, is preferably formed not only under the gate electrode but also under regions including the outside of the gate edge in longitudinal direction of the gate. Thus, in the case where there is present a channel region which is not covered with the gate electrode, the channel region is preferably covered with the gate insulating film or memory function parts, which will be described later.

The memory function part at least has a film or a region having a function of holding electric charges, or storing and holding electric charges, or a function of trapping electric charges. Materials implementing these functions include: silicon nitride; silicon; silicate glass including impurities such as phosphorus or boron; silicon carbide; alumina; high-dielectric substances such as hafnium oxide, zirconium oxide, or tantalum oxide; zinc oxide; and metals. The memory function part may be formed into single-layer or multi-layer structure of: for example, an insulating film containing a silicon oxide film; an insulating film incorporating a conductive film or a semiconductor layer inside; and an insulating film containing one or more semiconductor dots or semiconductor dots. Among these, the silicon oxide is preferable because it can achieve a large hysteresis property by the presence of a number of levels for trapping electric charges, and has good holding characteristics in that the electric-charge holding time is long and that there hardly occurs leakage of electric charges caused by generation of leakage paths, and further because it is a material normally used in LSI process.

Use of an insulating film containing inside an insulating film having a charge holding function such as a silicon nitride film enables increase of reliability relating to memory holding. Since the silicon nitride film is an insulator, electric charges of the entire silicon nitride film will not be immediately lost even if part of the electric charges is leaked. Further, in the case of arraying a plurality of storage devices, even if the distance between the storage devices is shortened and adjacent memory function parts come into contact with each other, information stored in each memory function part is not lost unlike the case where the memory function part is made from a conductor. Also, it becomes possible to dispose a contact plug closer to the memory function part, or in some cases it becomes possible to dispose the contact plug so as to overlap with the memory function part, which facilitates miniaturization of the storage devices.

For further increase of the reliability relating to the memory holding, the insulator having a function of holding electric charges is not necessarily needed to be in the film shape, and insulators having the function of holding an electric charge are preferably present in an insulating film in a discrete manner. More specifically, it is preferable that an insulator is dispersed like dots over a material having difficulty in holding electric charges, such as silicon oxide.

Also, use of an insulator film containing inside a conductive film or a semiconductor layer as a memory function part enables free control of quantity of electric charges injected into the conductor or the semiconductor, thereby bringing about an effect of facilitating achieving multi level cell.

Further, using an insulator film containing one or more conductor or semiconductor dots as a memory function part facilitates execution of write and erase due to direct tunneling of electric charges, thereby bringing about an effect of reduced power consumption.

More specifically, it is preferable that the memory function part further contains a region that obstructs escape of electric charges or a film having a function of obstructing escape of electric charges. Those fulfilling the function of obstructing escape of electric charges include a silicon oxide.

The memory function part is formed on the both sides of the gate electrode directly or through an insulating film, and it is disposed on a semiconductor substrate (a well region, a body region, or a source/drain region or a diffusion region) directly or through the gate insulating film or the insulating film. Charge holding films on the both sides of the gate electrode may be formed so as to cover the entirety or a part of side surfaces of the gate electrode directly or through the insulating film. In the case of using a conductive film as the charge holding film, the charge holding film is preferably disposed with interposition of an insulating film so that the charge holding film is not brought into direct contact with a semiconductor substrate (a well region, a body region, or a source/drain region or a diffusion layer region) or the gate electrode. This is implemented by, for example, a multi-layer structure composed of a conductive film and an insulating film, a structure of dispersing a conductive film like dots in an insulating film, and a structure of disposing a conductive film within part of a side-wall insulating film formed on the side wall of the gate.

The memory function part preferably has a sandwich structure in which a film made of a first insulator for storing electric charges is interposed in between a film made of a second insulator and a film made of a third insulator. Since the first insulator for storing electric charges is in the film shape, it becomes possible to increase electric charge concentration in the first insulator in a short period of time by injection of electric charges and also to uniform the electric charge distribution. In the case where the electric charge distribution in the first insulator for storing electric charges is not uniform, there is a possibility that electric charges move inside the first insulator during being held and so the reliability of the memory devices is deteriorated. Also, the first insulator for storing electric charges is separated from conductor portions (a gate electrode, a diffusion layer region, and a semiconductor substrate) with another insulating film, which may restrain leakage of electric charges and makes it possible to obtain sufficient holding time. Therefore, the above sandwich structure enables high-speed rewrite operations, increased reliability, and obtainment of sufficient holding time of the storage device. The memory function part that fulfils the above conditions is more preferably structured such that the first insulator is a silicon nitride film, and the second and the third insulators are silicon oxide films. The silicon nitride film may achieve large hysteresis property by the presence of a number of levels for trapping electric charges. Also, the silicon oxide film and the silicon nitride film are preferable because they are materials used in LSI process quite typically. Further, as the first insulator, in addition to silicon nitride, there may be used such materials as hafnium oxide, tantalum oxide, and yttrium oxide. As the second and third insulators, in addition to the silicon oxide, such material as aluminum oxide may be used. It is noted that the second and third insulators may be of different materials or may be of the same material.

The memory function part is formed on both sides of the gate electrode, and disposed on the semiconductor substrate (a well region, a body region, or a source/drain region or a diffusion layer region).

The charge holding film contained in the memory function part is formed on both sides of the gate electrode directly or through an insulating film, and it is disposed on the semiconductor substrate (a well region, a body region, or a source/drain region or a diffusion layer region) directly or through the gate insulating film or the insulating film. The charge holding films on both sides of the gate electrode are preferably formed so as to cover all or part of side walls of the gate electrode directly or thought the insulating film. In an application where the gate electrode has a recess portion on the lower edge side, the charge holding film may be formed so as to fill the entire recess portion or part of the recess portion directly or through the insulating film.

Preferably, the gate electrode is formed only on the side wall of the memory function part or formed such that the upper portion of the memory function part is not covered. In such disposition, it becomes possible to dispose a contact plug closer to the gate electrode, which facilitates miniaturization of the storage devices, or memory devices. Also, the memory devices having such simple disposition are easily manufactured, resulting in an increased yield.

The source/drain regions are disposed on the side of the memory function parts opposed from the gate electrode as diffusion regions having a conductivity type opposite to that of the semiconductor substrate or of the well region. In the portion where the source/drain region is joined to the semiconductor substrate or the well region, impurity concentration is preferably sharp. This is because the sharp impurity concentration efficiently generate hot electrons and hot holes with low voltages, which enables high-speed operations with lower voltages. The junction depth of the source/drain region is not particularly limited and so it is adjustable where necessary, according to performance and the like of a memory device to be manufactured. It is noted that if an SOI substrate is used as the semiconductor substrate, the junction depth of the source/drain region may be smaller than the film thickness of a surface semiconductor layer, though preferably the junction depth is almost equal to the film thickness of the surface semiconductor layer.

The source/drain region may be disposed so as to be overlapped with the edge of the gate electrode, or may be disposed so as to be offset from the edge of the gate electrode. Particularly, it is preferable that the source/drain region is offset relative to the edge of the gate electrode. This is because in this case, when voltage is applied to the gate electrode, easiness of inversion of the offset region under the charge holding film is largely changed by an electric charge amount stored in the memory function part, resulting in increased memory effect and reduced short channel effect. It is noted, however, that too much offset extremely reduces drive current between the source and the drain. Therefore, it is preferable that an offset amount, that is a distance from one edge of the gate electrode to the source or drain region closer thereto in the longitudinal direction of the gate, is shorter than the thickness of the charge holding film parallel to the longitudinal direction of the gate. What is particularly important is that at least part of the electric charge storage region in the memory function part overlaps with the source/drain region as a diffusion layer region. This is because the nature of memory devices or cells constituting the IC card of the present invention is to rewrite memory with an electric field crossing the memory function part by voltage difference between the gate electrode present only on the side wall portion of the memory function part and the source/drain region. The offset amount should be selected such that both the memory effect and the drive current have appropriate values, or are compatible with each other.

Part of the source/drain region may be extended up to the position higher than the surface of the channel region, that is, the lower face of the gate insulating film. In this case, it is appropriate that a conductive film is laid on a source/drain region formed in the semiconductor substrate in an integrated manner with the source/drain region. Examples of the conductive film include semiconductors such as polysilicon and amorphous silicon, silicide, and the above described metals and high-melting metals. Among these, the polysilicon is preferable. Since the polysilicon is extremely larger in impurity diffusion speed than the semiconductor substrate, it is easy to shallow the junction depth of the source/drain region in the semiconductor substrate, and it is easy to control short channel effect. In this case, it is preferable that the source/drain region is disposed such that at least part of the charge holding film is sandwiched between part of the source/drain region and the gate electrode.

The memory device of the present invention uses a single gate electrode formed on the gate insulating film, a source region, a drain region, and a semiconductor substrate as four terminals, and executes write, erase and read operations by giving specified potential to each of these four terminals. An example of the principle of a specific operation and operation voltages will be described later. When the storage devices of the present invention are disposed in an array to constitute a memory cell array, a single control gate is capable of control each storage device, which makes it possible to decrease the number of word lines.

The storage device of the present invention can be formed by a normal semiconductor fabrication process, for example, by a method similar to a method for forming a multilayer-structured side wall spacer on the side wall of a gate electrode. More specifically, there is a method in which after the gate electrode is formed, a multilayer composed of an insulating film (second insulator), an electric charge storage film (first insulator), and an insulating film (second insulator) is formed and etched back under an appropriate condition to leave the film in the form of a side wall spacer. In addition, depending on the structure of a desired memory function part, conditions and deposits in forming the side wall may be appropriately selected.

Specific examples of the storage devices to be used in the IC card of the present invention will be described below.

### Embodiment 1

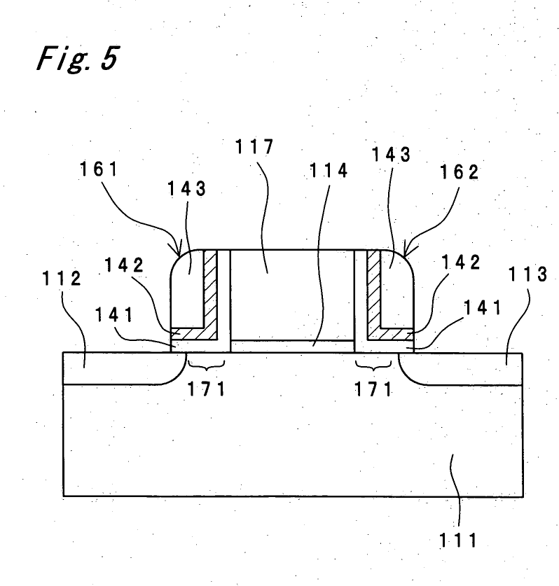

In a storage device in this embodiment as shown in FIG. 5, each memory function parts 161, 162 is composed of a region for holding electric charges (the region for storing electric charges, which may be a film having a function of holding electric charges) and a region for obstructing release of electric charges (which may be a film having a function of obstructing release of electric charges). The memory function part has, for example, ONO (Oxide Nitride Oxide) structure. More specifically, the memory function parts 161, 162 are each structured in the state that a silicon nitride film 142 as a first insulator is interposed between a silicon oxide film 141 as a second insulator and a silicon oxide film 143 as a third insulator. Here, the silicon nitride film 142 implements a function of holding electric charges. The silicon oxide films 141, 143 implement a function of obstructing release of the electric charges stored in the silicon nitride film.

Also, the regions (silicon nitride films 142) for holding electric charges in the memory function parts 161, 162 are overlapped with the diffusion layer regions 112, 113. Herein, the term “overlap” is used to refer to the state that at least part of the region (silicon nitride film 142) for holding electric charges is present on at least part of the diffusion layer region 112, 113. There are also shown a semiconductor substrate 111, a gate insulating film 114, a gate electrode 117, and offset regions 171 (between the gate electrode and the diffusion layer regions). Though not shown in the drawing, the uppermost surface area of the semiconductor substrate 111 under the gate insulating film 114 serves as a channel region.

Description will be given of an effect of overlapping the region 142 for holding electric charges in the memory function parts 161, 162 and the diffusion layer regions 112, 113.

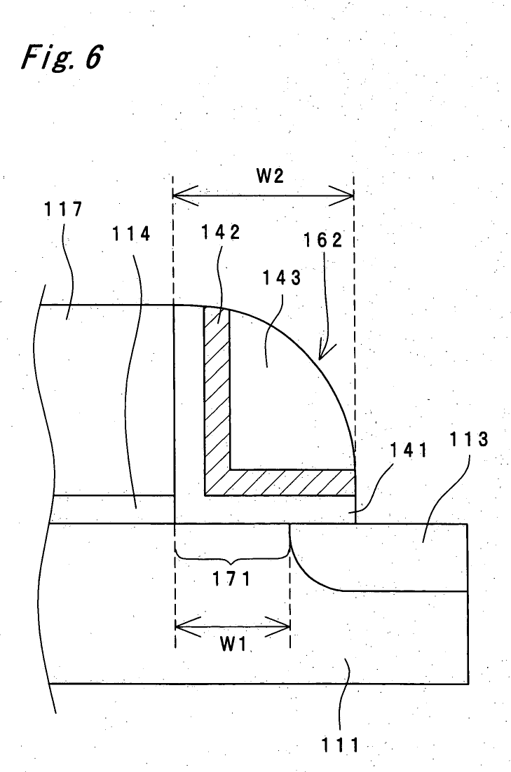

FIG. 6 is an enlarged view showing the vicinity of the memory function part 162 that is on the right side of FIG. 5. Reference numeral W1 denotes an offset amount between the gate insulating film 114 and the diffusion layer region 113. Also, reference numeral W2 denotes the width of the memory function part 162 on the cross sectional plane in channel length direction of the gate electrode. Since an edge of the silicon nitride film 142 on the side away from the gate electrode 117 in the memory function part 162 is aligned with an edge of the memory function part 162 on the side away from the gate electrode 117, the width of the memory function part 162 is defined as W2. An overlap amount between the memory function part 162 and the diffusion layer region 113 is represented by an expression of W2-W1. What is particularly important is that the silicon nitride film 142 in the memory function part 162 is overlapped with the diffusion layer region 113, that is, the silicon nitride film 142 is configured such that the relation of W2>W1 is satisfied.

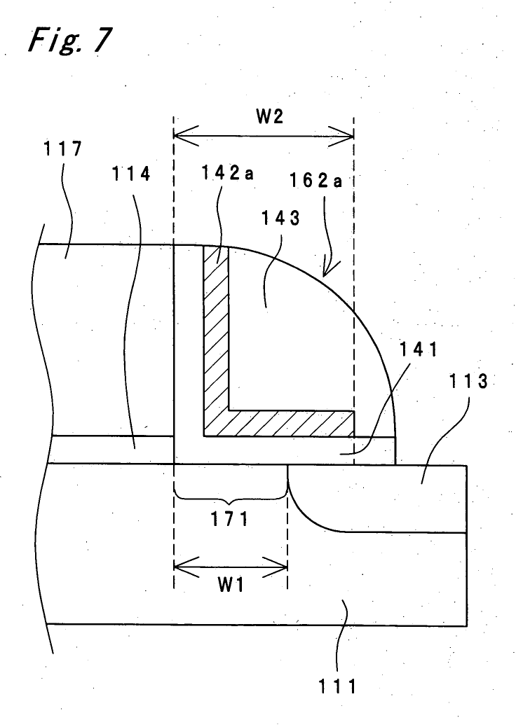

In the case where the edge of the silicon nitride film 142a on the side away from the gate electrode in the memory function part 162a is not aligned with the edge of the memory function part 162a on the side away from the gate electrode as shown in FIG. 7, W2 may be defined as the width from the edge of the gate electrode to the edge of the silicon nitride film 142a on the side away from the gate electrode.

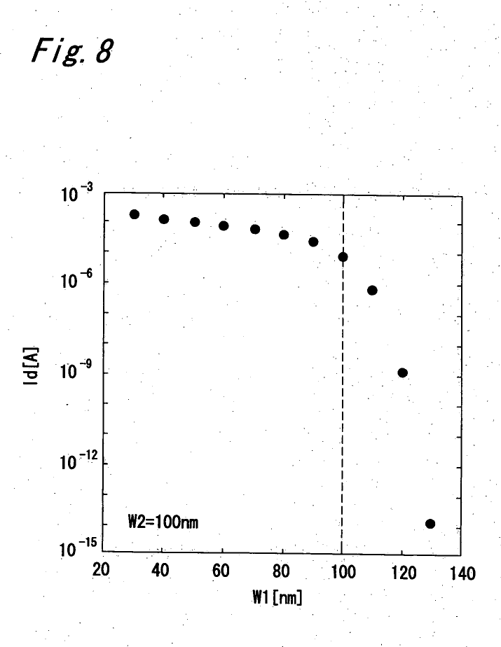

FIG. 8 shows a drain current Id in the structure of FIG. 6 with the width W2 of the memory function part 162 being fixed to 100 nm and the offset amount W1 being varied. Herein, the drain current is obtained by device simulation performed under the conditions that the memory function part 162 is in erased state (holes are stored), and that the diffusion layer regions 112, 113 are set to be a source electrode and a drain electrode, respectively.

As shown in FIG. 8, with W1 being 100 nm or more (i.e., when the silicon nitride film 142 and the diffusion layer region 113 are not overlapped), the drain current shows rapid reduction. Since a drain current value is almost in proportion to a read operation speed, memory performance is rapidly deteriorated when W1 is 100 nm or more. In the range where the silicon nitride film 142 and the diffusion layer region 113 are overlapped, the drain current shows mild reduction. Therefore, it is preferable that at least part of the silicon nitride film 142 that is a film having a function of holing electric charges is overlapped with the source/drain region.

Based on the above-described result of the device simulation, memory cell arrays are manufactured with W2 being fixed to 100 nm, and W1 being set to 60 nm and 100 nm as design values. When W1 is 60 nm, the silicon nitride film 142 is overlapped with the diffusion layer regions 112, 113 by 40 nm as a design value, and when W1 is 100 nm, there is no overlap as a design value. As a result of measuring read times of these memory cell arrays and comparing them in worst cases considering dispersion, it was found out that the case where W1 was 60 nm as a design value was 100 times faster in readout access time. From a practical standpoint, it is preferable that the read access time is 100 nanoseconds or less per bit. It was found out, however, that this condition was never satisfied in the case of W1=W2. It was also found out that W2−W1>10 nm was more preferable in consideration of manufacturing dispersion.

For reading information stored in the memory function part 161, it is preferable to set the diffusion layer region 112 as a source electrode and the diffusion layer region 113 as a drain region, as in the device simulation, and to form a pinchoff point on the side closer to the drain region of the channel region. More specifically, in reading information stored in one of two memory function parts, the pinchoff point is preferably formed in a region closer to the other memory function part of the channel region. This makes it possible to detect stored information in one memory function part 161, for example, with good sensitivity regardless of the storage condition of the other memory function part 162, resulting in large contribution to implementation of two-bit operation.

In the case of storing information only in one of the two memory function parts 161, 162, or in the case of using these two memory function parts 161, 162 in the same storing condition, an pinchoff point is not necessarily formed in read operations.

Although not shown in FIG. 5, a well region (P type well in the case of N-channel device) is preferably formed at the surface of the semiconductor substrate 111. Forming the well region facilitates control of electrical characteristics (withstand voltage, junction capacitance, and short channel effect) while maintaining impurity concentration of the channel region optimum for memory operations (rewrite operation and read operation).

From the viewpoint of improving memory holding characteristic, the memory function part preferably incorporates a charge holding film having a function of holing electric charges, and an insulating film. This embodiment uses the silicon nitride film 142 as a charge holding film having levels for trapping electric charges, and the silicon oxide films 141, 143 as insulating films having a function of preventing the electric charges stored in the charge holding film from dispersing. The memory function part having the charge holding film and the insulating film makes it possible to prevent electric charges from dispersing and to improve holding characteristic. Further, compared with a memory function part composed of only a charge holding film, it becomes possible to appropriately decrease the volume of the charge holding film. Appropriate decrease of the volume of the charge holding film makes it possible to restrain movement of electric charges in the charge holding film and to control occurrence of characteristic change due to movement of electric charges during memory holding.

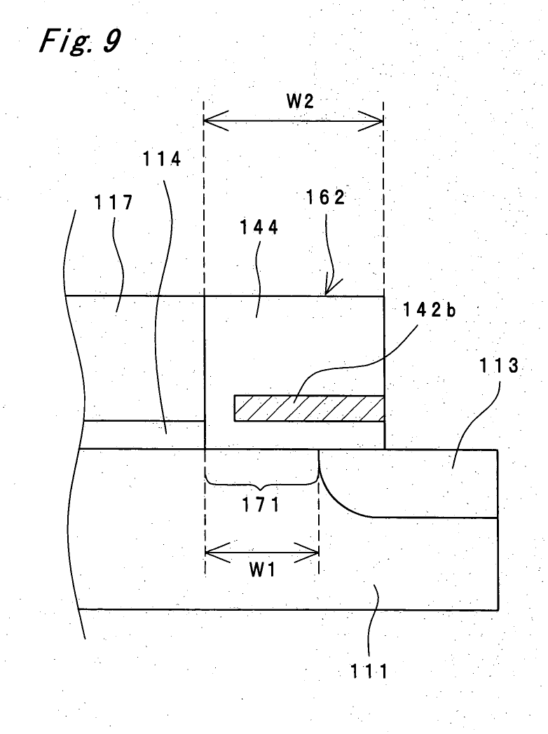

Also, it is preferable that the memory function part contains a charge holding film disposed approximately parallel to the surface of the gate insulating film. In other words, it is preferable that the surface of the charge holding film in the memory function part is disposed so as to be at a constant distance from the surface of the gate insulating film. More particularly, as shown in FIG. 9, a charge holding film 142b in the memory function part 162 has a face approximately parallel to the surface of the gate insulating film 114. In other words, the charge holding film 142b is preferably formed to have a uniform height from the height corresponding to the surface of the gate insulating film 114. The presence of the charge holding film 142b approximately parallel to the surface of the gate insulating film 114 in the memory function part 162 makes it possible to effectively control formation of an inversion layer in the offset region 171 with use of an amount of electric charges stored in the charge holding film 142b, thereby enabling increase of memory effect. Also, by placing the charge holding film 142b approximately parallel to the surface of the gate insulating film 114, change of memory effect is kept relatively small even with a dispersed offset amount (W1), enabling restraint of memory effect dispersion. In addition, movement of electric charges toward upper side of the charge holding film 142b is controlled, and therefore characteristic change due to the movement of electric charges during memory holding can be restrained.

Furthermore, the memory function part 162 preferably contains an insulating film (e.g., a portion of the silicon oxide film 144 on the offset region 171) that separates the charge holding film 142b approximately parallel to the surface of the gate insulating film 114 from the channel region (or the well region). This insulating film restrains dissipation of the electric charges stored in the charge holding film, thereby contributing to obtaining a storage device with better holding characteristics.

It is noted that controlling the film thickness of the charge holding film 142b as well as controlling the film thickness of the insulating film under the charge holding film 142b (a portion of the silicon oxide film 144 on the offset region 171) to be constant make it possible to keep the distance from the surface of the semiconductor substrate to the electric charges stored in the charge holding film approximately constant. More particularly, the distance from the surface of the semiconductor substrate to the electric charges stored in the charge holding film 142b can be controlled to be within the range of from a minimum film thickness value of the insulating film under the charge holding film 142b to the sum of a maximum film thickness of the insulating film under the charge holding film 142b and a maximum film thickness of the charge holding film 142b. Consequently, the concentration of electric lines of force generated by the electric charges stored in the charge holding film 142b becomes roughly controllable, and therefore dispersion of the degree of memory effect of the memory devices can be minimized.

### Embodiment 2

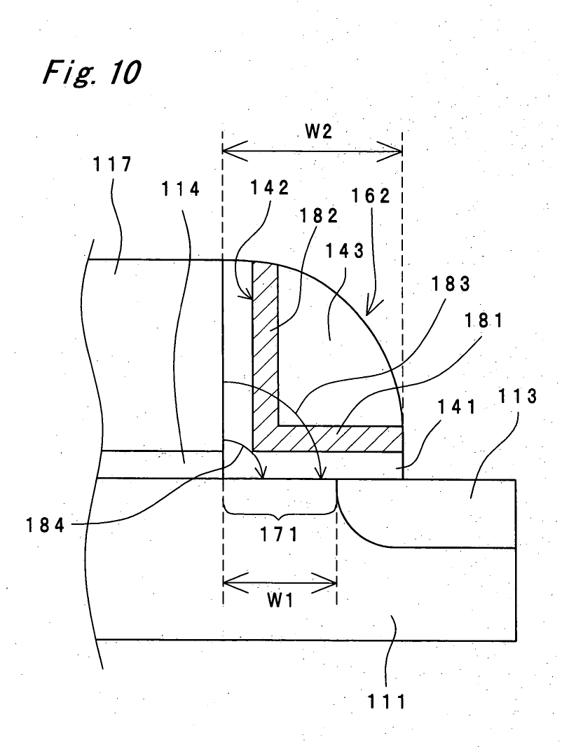

In Embodiment 2, a charge holding film 142 in the memory function part 162 has an approximately uniform film thickness as shown in FIG. 10. Further, the charge holding film 142 includes a first portion 181 as an example of a portion having a surface approximately parallel to the surface of the gate insulating film 114 and a second portion 182 as an example of a portion extending in a direction approximately parallel to a side face of the gate electrode 117.

When a positive voltage is applied to the gate electrode 117, an electric line of force in the memory function part 162 passes the silicon nitride film 142 totally twice through the first portion 181 and the second portion 182 as shown with arrow line 183. It is noted that when a negative voltage is applied to the gate electrode 117, the direction of the electric line of force is reversed. Herein, a relative permittivity, or dielectric constant of the silicon nitride film 142 is approx. 6, while a dielectric constant of silicon oxide films 141, 143 is approx. 4. Eventually, an effective dielectric constant of the memory function part 162 in the direction of electric line of force 183 becomes larger than that in the case where the charge holding film 142 includes only the first portion 181, which makes it possible to decrease the potential difference between both edges of the electric line of force. More specifically, a large part of the voltage applied to the gate electrode 117 is used to reinforce electric fields in the offset region 171.

Electric charges are injected into the silicon nitride film 142 in rewrite operations because generated electric charges are pulled by electric fields in the offset region 171. As a consequence of the charge holding film 142 including the second portion 182, increased electric charges are injected into the memory function part 162 in rewrite operations, thereby increasing a rewrite speed.

In the case where the silicon oxide film 143 is replaced with a silicon nitride film, more specifically, in the case where the upper surface of the charge holding film is not at a constant height relative to the surface of the gate insulating film 114, movement of electric charges toward upper side of the silicon nitride film becomes outstanding, and holding characteristics are deteriorated.

Instead of silicon oxide film, the memory function part is more preferably formed from high-dielectric substances such as hafnium oxide having an extremely large dielectric constant, or relative permittivity.

Further, the memory function part more preferably includes an insulating film (a portion of the silicon oxide film 141 on the offset region 171) that separates the charge holding film approximately parallel to the surface of the gate insulating film from the channel region (or the well region). This insulating film restrains dissipation of the electric charges stored in the charge holding film, thereby enabling further improvement of holding characteristics.

Also, the memory function part more preferably includes an insulating film (a portion in contact with the gate electrode 117 of the silicon oxide film 141) that separates the gate electrode from the charge holding film extending in the direction approximately parallel to the side face of the gate electrode. This insulating film prevents injection of electric charges from the gate electrode into the charge holding film to thereby prevent change of electrical characteristics, which may increase reliability of the storage device.

Further, similar to Embodiment 1, it is preferable that the film thickness of the insulating film under the charge holding film 142 (a portion of the silicon oxide film 141 on the offset region 171) is controlled to be constant, and further the film thickness of the insulating film disposed on the side face of the gate electrode (a portion of the silicon oxide film 141 in contact with the gate electrode 117) is controlled to be constant. Consequently, the concentration of electric lines of force generated by the electric charges stored in the charge holding film 142 becomes roughly controllable, and leakage of electric charges can be prevented.

### Embodiment 3

This Embodiment 3 relates to optimization of the distance between a gate electrode, a memory function part, and a source/drain region.

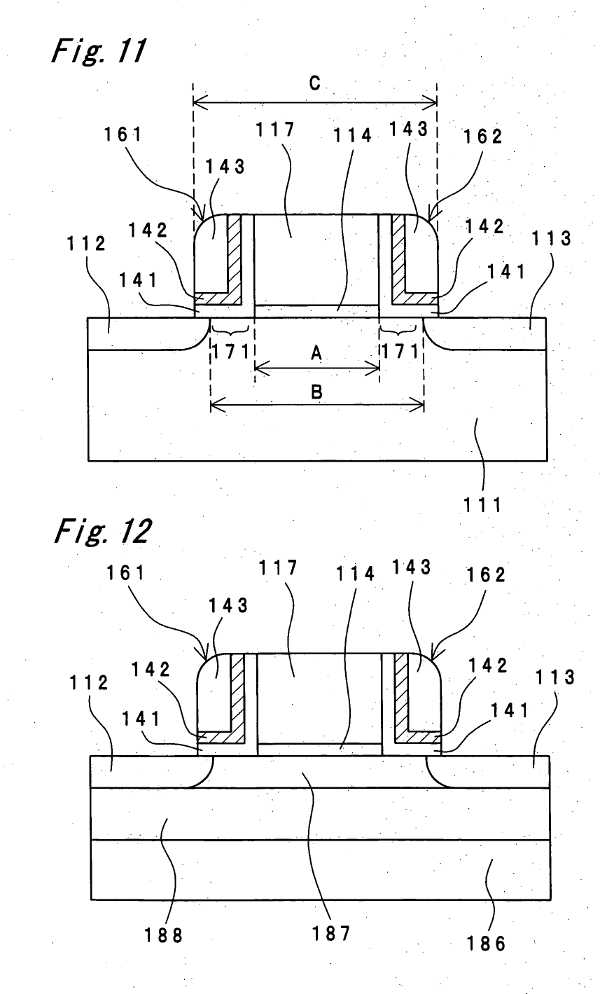

As shown in FIG. 11, reference symbol A denotes a gate electrode length in the cross section in the channel length direction, reference symbol B denotes a distance (channel length) between source and drain regions, and reference symbol C denotes a distance from an outer edge of one memory function part to an outer edge of the other memory function part, more specifically a distance from the outer edge (on the side away from the gate electrode) of a film having a function of holding the electric charges in one memory function part to the outer edge (on the side away from the gate electrode) of a film having a function of holding the electric charges in the other memory function part in the cross section in the channel length direction.

First, it is preferable that the relationship of B<C holds. In the channel region, there is present an offset region 171 between a portion under the gate electrode 117 and each of the source/drain regions 112, 113. Since B<C, the electric charges stored in the memory function parts 161, 162 (silicon nitride films 142) effectively vary invertibility in the entire part of the offset region 171. As a result, memory effect is increased, and a high-speed read operation is particularly enabled.

Also, when the gate electrode 117 and the source/drain regions 112, 113 are offset relative to each other, that is, when an equation A<B is satisfied, invertibility of the offset region when a voltage is applied to the gate electrode 117 is largely changed by an electric charge amount stored in the memory function parts 161, 162. Consequently, memory effect increases and short channel effect can be reduced. However, as long as the memory effect is effective, the offset region is not necessarily required. Even when the offset region 171 is not present, if the impurity concentration in the source/drain regions 112, 113 is sufficiently small, the memory effect can still be effective in the memory function parts 161, 162 (silicon nitride film 142).

Therefore, the state of A<B<C is most preferable.

### Embodiment 4

A storage device in Embodiment 4 has essentially the same structure as that in Embodiment 1 except that in the present embodiment, the semiconductor substrate is an SOI substrate, as shown in FIG. 12.

The storage device is structured such that a buried oxide film 188 is formed on a semiconductor substrate 186, and on top of the buried oxide film 188, an SOI layer is further formed. In the SOI layer, there are formed diffusion layer regions 112, 113, and other areas constitute a body region 187.

This storage device also brings about the effects similar to those of the storage device in Embodiment 3. Further, since the junction capacitance between the diffusion layer regions 112, 113 and the body region 187 can be considerably reduced, it becomes possible to increase a device speed and to decrease power consumption.

### Embodiment 5

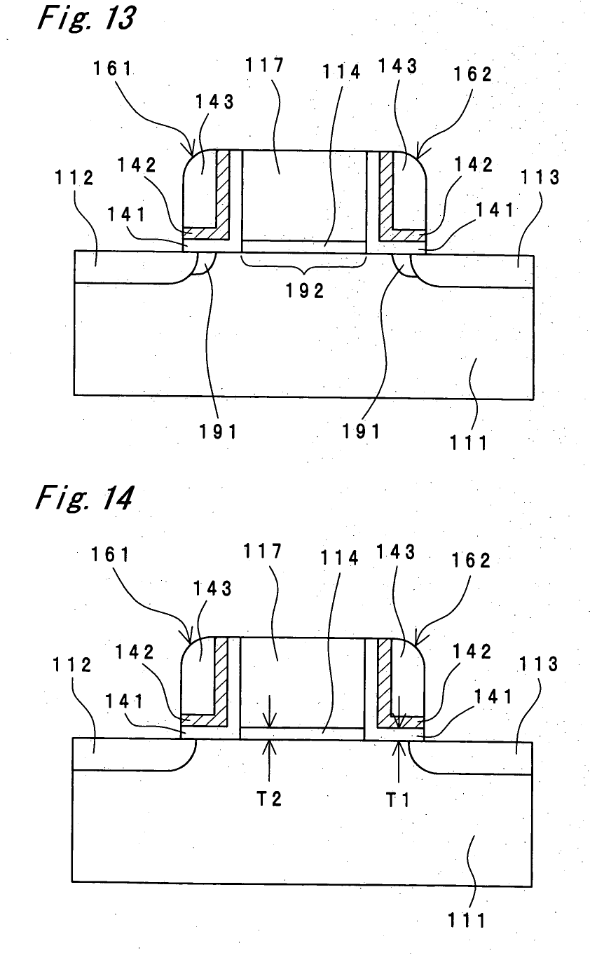

A storage device in Embodiment 5 has essentially the same structure as that in Embodiment 1, except that in Embodiment 5, a P type highly-concentrated region 191 is provided, as shown in FIG. 13, in the vicinity of the channel side of N type source/drain regions 112, 113.

More specifically, the concentration of P type impurity (e.g., boron) in the P type highly-concentrated region 191 is higher than the concentration of P type impurity in the region 192. An appropriate value of the P type impurity concentration in the P type highly-concentrated region 19.1 is, for example, around 5×10¹⁷ to 1×10¹⁹ cm⁻³. Also, a value of the P type impurity concentration in the region 192 may be set to, for example, 5×10¹⁶ to 1×10¹⁸ cm⁻³.

Providing the P type highly-concentrated region 191 makes the junction between the diffusion layer region 112, 113 and the semiconductor substrate 111 steep right under the memory function parts 161, 162. This facilitates generation of hot carriers in write and erase operations, thereby enabling reduction of voltage in write operations and erase operations or implementing high-speed write operations and erase operations. Further, since the impurity concentration in the region 192 is relatively low, a threshold value when the memory is in erased state is small and so the drain current becomes large. Consequently, a read speed is increased. This makes it possible to provide a storage device having low rewrite voltage or a high rewrite speed, and having a high read speed.

Also in FIG. 13, by providing the P type highly-concentrated region 191 in a position adjacent to the source/drain region and on the lower side of the memory function part 161, 162 (that is a position not right under the gate electrode), a threshold value of the entire transistor shows considerable increase. The degree of this increase is extremely larger than that in the case where the P type highly-concentrated region 191 is right under the gate electrode 117. When write electric charges (electrons in the case where the transistor is N channel type) are stored in the memory function parts 161, 162, the difference becomes larger. When enough erase electric charges (holes in the case where the transistor is N channel type) are stored in the memory function part, a threshold value of the entire transistor is decreased down to a value determined by the impurity concentration in the channel region (region 192) under the gate electrode 117. More specifically, the threshold value in the erased state does not depend on the impurity concentration in the P type highly-concentrated region 191, whereas the threshold value in the written state is largely influenced thereby. Therefore, disposing the P type highly-concentrated region 191 under the memory function parts 161, 162 and adjacent to the source/drain region largely changes the threshold value only in the written state, thereby enabling remarkable increase of memory effect (difference of threshold values in the erased state and the written state).

### Embodiment 6

A storage device in Embodiment 6 has essentially the same structure as that in Embodiment 1, except that in Embodiment 6, the thickness T1 of the insulating film 141 that separates the memory function part (silicon nitride film 142) from the channel region or the well region is smaller than the thickness T2 of the gate insulating film 114, as shown in FIG. 14.

The gate insulating film 114 has a lower limit of the thickness T2 because of the request for withstand voltage in memory rewrite operations. However, the thickness T1 of the insulating film can be smaller than T2 regardless of the request for withstand voltage.

In the storage device in Embodiment 6, the thickness T1 of the insulating film has high design freedom as stated above because of the following reason. In the storage device in Embodiment 6, the insulating film that separates the charge holding film from the channel region or the well region is not interposed between the gate electrode 117 and the channel region or well region. Consequently, the insulating film that separates the charge holding film from the channel region or the well region does not receive direct influence from the high electric fields that act upon a region between the gate electrode 117 and the channel region or the well region, but receives influence from relatively weak electric fields expanding from the gate electrode 117 in horizontal direction. As a result, despite the request for withstand voltage to the gate insulating film 114, it becomes possible to make T1 smaller than T2. Contrary to this, for example in EEPROM as typified by flash memory, an insulating film that separates a floating gate from the channel region or the well region is interposed between a gate electrode (control gate) and the channel region or the well region, so that the insulating film receives direct influence from high electric fields of the gate electrode. In EEPROM, therefore, the thickness of the insulating film that separates the floating gate from the channel region or the well region is limited, which hinders optimization of the functions of a memory device.

As is apparent from the above, an essential reason of high freedom of T1 is the fact that the insulating film that separates the charge holding film from the channel region or the well region in the memory device of Embodiment 6 is not interposed between the gate electrode 117 and the channel region or the well region.

Decreasing the thickness T1 of the insulating film facilitates injection of electric charges into the memory function parts 161, 162, decreases voltage for write operations and erase operations, or enables high-speed write operations and erase operations. In addition, since an electric charge amount induced in the channel region or the well region increases when electric charges are stored in the silicon nitride film 142, increased memory effect may be implemented.

Some electric lines of force in the memory function part, which have a short length, do not pass the silicon nitride film 142 as shown with arrow 184 in FIG. 10. Since electric field strength is relatively large on such a short electric line of force, the electric fields along the electric line of force plays an important role in rewrite operations. By decreasing the thickness T1 of the insulating film, the silicon nitride film 142 moves to the lower side of the FIG. 10, so that the electric line of force shown with the arrow 183 passes the silicon nitride film 142. As a consequence, an effective dielectric constant in the memory function part 161, 162 along the electric line of force 184 becomes large, which makes it possible to make potential difference between both ends of the electric line of force 184 smaller. Therefore, most part of voltage applied to the gate electrode 117 is used to strengthen the electric fields in the offset region, thereby implementing high-speed write operations and erase operations.

As is clear from the above, the thickness T1 of the insulating film 141 and the thickness T2 of the gate insulating film 114 are defined as T1<T2 so as to decrease voltage in write operations and erase operations or implement high-speed write operations and erase operations, and to enable further increase of memory effect without degrading withstand voltage capability of the memory.

It is noted that the thickness T1 of the insulating film is preferably at least 0.8 nm, which is a limit at which uniformity in manufacturing process or certain level of film quality is maintained and holding characteristics do not suffer extreme deterioration.

More specifically, in the case of a liquid crystal driver LSI which has a severe design rule and requires high withstand voltage, maximum 15 V to 18 V voltage is necessary for driving liquid crystal panel TFTs (thin-film transistors). Eventually, it is not possible to make the gate oxide film thinner. In the case of mounting nonvolatile memory devices of the present invention as an image adjuster together with other devices on the liquid crystal driver LSI, the memory device of the present invention enables optimum design of the thickness of an insulating film that separates the charge holding film (silicon nitride film 142) from the channel region or the well region independently of the gate insulating film. For example, in a storage device with a gate electrode length (word line width) of 250 nm, T1 and T2 may be separately set like T1=20 nm and T2=10 nm, fulfilling a storage device with good write efficiency. (Short channel effect is not generated even though T1 is larger than that of normal logic transistors, because the source/drain region is offset from the gate electrode.)

### Embodiment 7

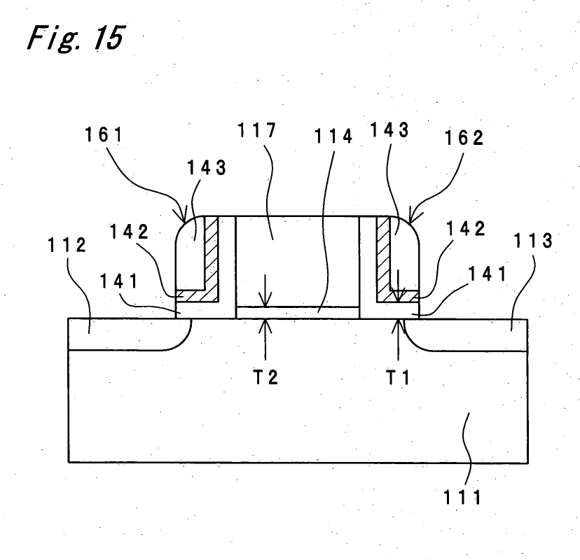

A storage device in this embodiment has essentially the same structure as that in Embodiment 1 except that the thickness T1 of the insulating film (silicon oxide film 141) that separates the charge holding film (silicon nitride film 142) from the channel region or the well region is larger than the thickness T2 of the gate insulating film 114, as shown in FIG. 15.

The gate insulating film 114 has an upper limit of the thickness T2 because of the request for prevention of short channel effect of the device. However, the thickness T1 of the insulating film 141 is allowed to be larger than T2 regardless of the request for prevention of short channel effect. More specifically, as miniaturization scaling proceeds (the gate insulating film 114 becomes thinner), the thickness T1 of the insulating film (silicon oxide film 141) may be optimally designed independently of the thickness T2 of the gate insulating film, which implements the effect that the memory function parts 161, 162 will not disturb scaling.

In the storage device of Embodiment 7, the thickness T1 of the insulating film has high design freedom as stated above because, as is already described, the insulating film that separates the charge holding film from the channel region or the well region is not interposed between the gate electrode 117 and the channel region or the well region. As a result, despite the request for prevention of short channel effect to the gate insulating film 114, it becomes possible to make the thickness T1 of the insulating film larger than the thickness T2 of the gate insulating film 114.

Increasing the thickness of the insulating film 141 makes it possible to prevent dissipation of the electric charges stored in the memory holding bodies 161, 162 and to improve holing characteristics of the memory.

Therefore, setting the thickness T1 of the insulating film and the thickness T2 of the gate insulating film 114 as T1>T2 enables improvement of holding characteristics without deteriorating short channel effect of the memory.

It is noted that the thickness T1 of the insulating film is preferably 20 nm or less in consideration of reduction of a rewrite speed.

More specifically, a conventional nonvolatile memory as typified by flash memory is structured such that a selection gate electrode constitutes a write/erase gate electrode, and a gate insulating film (including a floating gate) corresponding to the write/erase gate electrode serves also as an electric charge storage film. Consequently, since the request for miniaturization (creation of thinner devices is essential for restraining short channel effect) conflicts with the request for securing reliability (in order to control leakage of stored electric charges, the thickness of an insulating film that separates a floating gate from the channel region or the well region cannot be decreased to smaller than approx. 7 nm), miniaturization of the device is difficult. In fact, according to ITRS (International Technology Roadmap for Semiconductors), miniaturization of a physical gate length down to approx. 0.2 micron or lower is not yet in sight. In the storage device of the present invention, independent designing of T1 and T2 is available as described above, and therefore miniaturization becomes possible. In the present invention, for example, in a storage device with a gate electrode length (word line width) of 450 nm, T1 and T2 are separately set as T2=4 nm and T1=7 nm, fulfilling a storage device free from generation of short channel effect. Short channel effect is not generated even though T2 is set larger than that of normal logic transistors, because the source/drain region 112, 113 is offset, or displaced away from the gate electrode 117. Also, since the source/drain region is offset from the gate electrode in the storage device of the present invention, miniaturization is further facilitated compared to normal logic transistors.

As described above, according to the storage device of the present invention, since an electrode for helping write and erase operations is not present above the memory function part, the insulating film that separates the charge holding film from the channel region or the well region does not directly receive the influence of high electric fields that would occur between the electrode helping write and erase operations and the channel region or the well region, but receives influence only from relatively weak electric fields expanding from the gate electrode in horizontal direction. This makes it possible to fulfill a storage device having the gate length miniaturized more than the gate length of the logic transistors.

### Embodiment 8

Embodiment 8 relates to a method of operating memory devices.

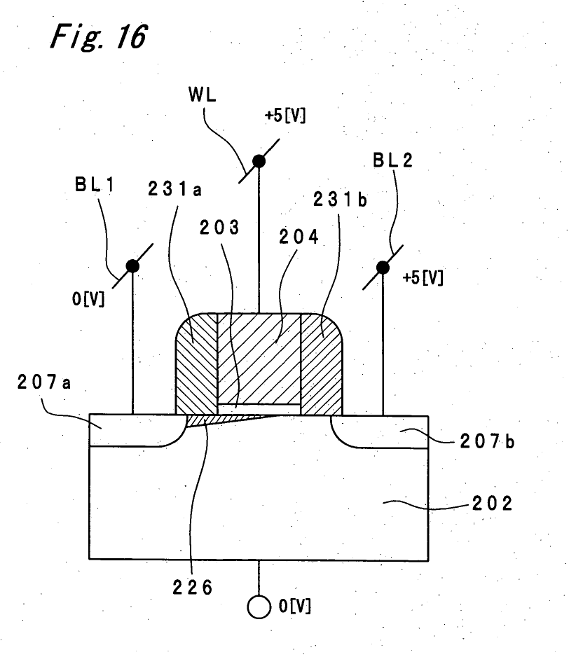

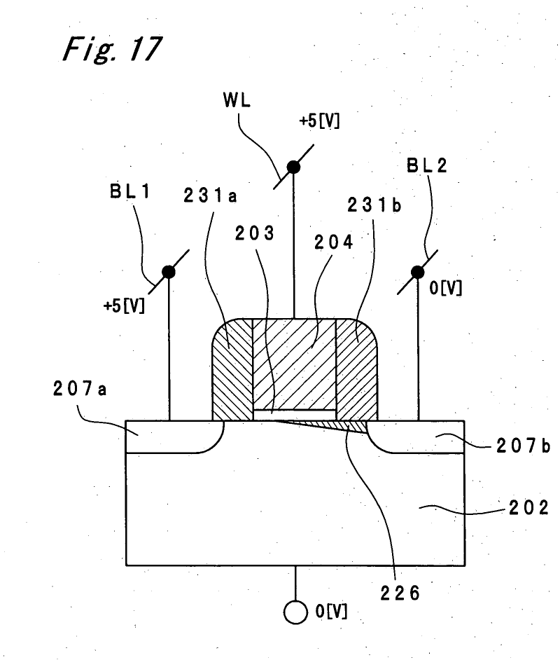

First, the write operation principle of the memory device will be described with reference to FIGS. 16 and 17. In these figures, reference numeral 203 denotes a gate insulating film, 204 denotes a gate electrode, WL denotes a word line, BL1 denotes a first bit line, and BL2 denotes a second bit line. The following will describe a case in which a first memory function part 231a and a second memory function part 231b have a function of holding electric charges.

It is noted that the term “write” refers to the action of injecting electrons into the memory function part 231a, 231b when the memory device is of N channel type. In the following description (including description about read method an erase method), it is assumed that the memory device is of N channel type.

In order to inject electrons (write) into the second memory function part 231b, as shown in FIG. 16, a first diffusion layer region 207a (having N-type conductivity) is set to be a source region and a second diffusion layer region 207b (having N-type conductivity) is set to be a drain region. For example, 0 V may be applied to the first diffusion layer region 207a and the P type well region 202, +5 V to the second diffusion layer region 207b, and +5 V to the gate electrode 204. Under these voltage conditions, an inversion layer 226 extends from the first diffusion layer region 207a (source region) but fails to reach the second diffusion layer region 207b (drain region), resulting in generating a pinchoff point. Electrons are accelerated by high electric fields from the pinchoff point to the second diffusion layer region 207b (drain region) and turn to be so-called hot electrons (high energy conductive electrons). By injecting these hot electrons into the second memory function part 231b, a write operation is executed. It is noted that in the vicinity of the first memory function part 231a, hot electrons are not generated and therefore the write operation is not executed.

In this way, electrons are injected to the second memory function part 231b so as to enable the write operation.

In order to inject electrons (write) into the first memory function part 231a, as shown in FIG. 17, the second diffusion layer region 207b is set to be a source region, and the first diffusion layer region 207a is set to be a drain region. For example, 0 V may be applied to the second diffusion layer region 207b and the P type well region 202, +5 V to the first diffusion layer region 207a, and +4 V to the gate electrode 204. Thus, by reversing the source and drain regions in the case of injecting electrons into the second memory function part 221b, electrons are injected into the first memory function part 231a for enabling a write operation.

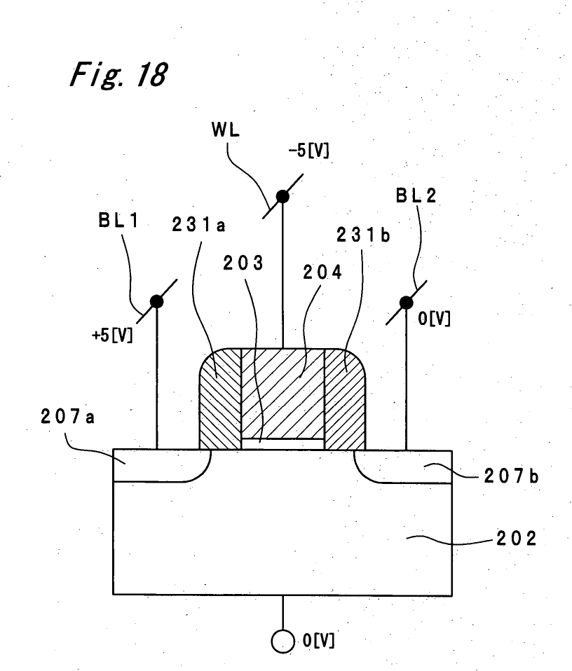

Next, an erase operation principle of the memory device will be described with reference to FIGS. 18, 19, and 20.

In a first method for erasing information stored in the first memory function part 231a, as shown in FIG. 18, a positive voltage (e.g., +5 V) is applied to the first diffusion layer region 207a while a voltage of 0 V is applied to the P-type well region 202, reverse bias is applied to the PN junction between the first diffusion layer region 207a and the P-type well region 202, and further, a negative voltage (e.g., −5 V) is applied to the gate electrode 204. At this time, in a portion of the PN junction in the vicinity of the gate electrode 204, the potential gradient is particularly steep due to the influence of the gate electrode 204 to which a negative voltage is applied. As a consequence, hot holes (high-energy holes) are generated by inter-band tunneling in a portion of the PN junction on the side of the P-type well region 202. The hot halls are pulled toward the gate electrode 204 having a negative potential, as a result of which hole injection to the first memory function part 231a is performed. Thus, an erase operation of the first memory function part 231a is executed. Here, a voltage of 0V is applied to the second diffusion layer region 207b.

For erasing information stored in the second memory function part 231b, potential of the first diffusion layer region 207a and potential of the second diffusion layer region 207b are reversed in the above process. More particularly, a voltage of 0 V is applied to the first diffusion layer region 207a while a voltage of +5 V is applied to the second diffusion layer region 207b.

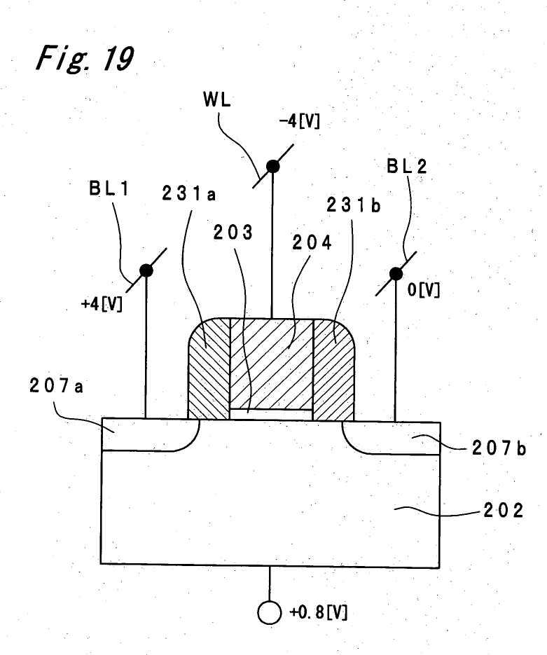

In a second method for erasing information stored in the first memory function part 231a, as shown in FIG. 19, a positive voltage (e.g., +4 V) is applied to the first diffusion layer region 207a, a voltage of 0 V is applied to the second diffusion layer region 207b, a negative voltage (e.g., −4 V) is applied to the gate electrode 204, and a positive voltage (e.g., +0.8 V) is applied to the P-type well region 202. In this case, forward voltage is applied to between the P-type well region 202 and the second diffusion layer region 207b, so that electrons are injected into the P-type well region 202. The injected electrons are diffused to the PN junction between the P-type well region 202 and the first diffusion layer region 207a, where the electrons are accelerated by strong electric fields to be hot electrons. The hot electrons generate electron-hole pairs in the PN junction. More specifically, by applying forward voltage to between the P-type well region 202 and the second diffusion layer region 207b, with the electrons injected into the P-type well region 202 being a trigger, hot holes are generated in the PN junction positioned on the opposite side. The hot holes generated in the PN junction are pulled toward the gate electrode 204 having negative potential, as a result of which hole injection into the first memory function part 231a is performed.

According to the second method, even in the case where there is not applied voltage sufficient enough for generating hot holes by interband tunneling in the PN junction between the P-type well region 202 and the first diffusion layer region 207a, the electrons injected from the second diffusion layer region 207b function as a trigger to generate electron-hole pairs in the PN junction so that hot holes are generated. Therefore, voltage in erase operations can be reduced. Particularly in the case where the diffusion layer regions 207a, 207b and the gate electrode 204 are offset with respect to each other, there is obtained less effect of providing a steep PN junction by the gate electrode 204 with a negative potential applied thereto. Therefore, although generation of hot holes by interband tunneling is difficult, the second method can cover this shortcoming and implement erase operations at low voltage.

It is noted that for erasing information stored in the first memory function part 231a, the first erasing method requires application of a voltage of +5 V to the first diffusion layer region 207a, whereas the second erasing method requires application of only +4 V. As is apparent from the above description, according to the second method, voltage in erase operations can be decreased, which makes it possible to decrease power consumption and restrain deterioration of the storage device due to hot carriers.

In either the first or the second erasing method, the storage device of the present invention hardly suffers excessive erasure. The excessive erasure is a phenomenon that along with increase in a hole amount stored in the memory function part, the threshold is lowered without saturation. This phenomenon is a serious problem of the EEPROM that typifies flash memories, which causes a fatal operational defect in which selection of storage devices is impossible particularly when the threshold becomes negative. In the storage device of the present invention, a large amount of holes, if stored in the memory function part, only induces electrons under the memory function part and imposes little influence on the potential in the channel region under the gate insulating film. As the threshold in erase operations depends on the potential under the gate insulating film, excessive erasure hardly occurs.

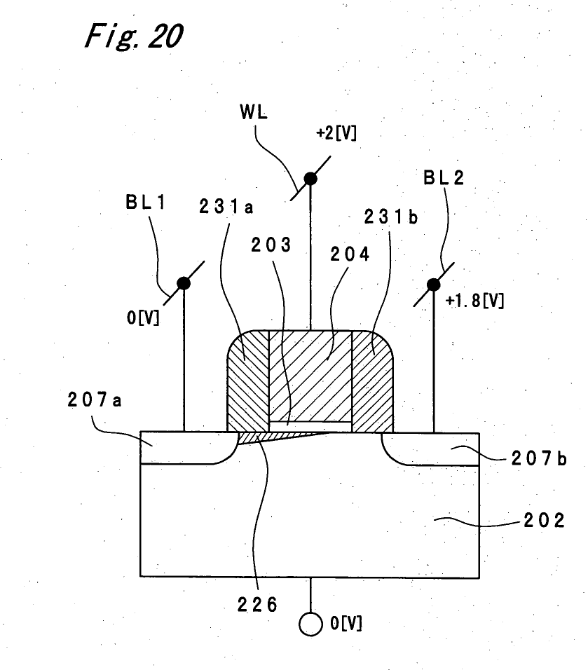

Next, description will be given of the principle of read operation of the memory device referring to FIG. 20.

In the case of reading information stored in the first memory function part 231a, the first diffusion layer region 207a is set to be a source region and the second diffusion layer region 207b is set to be a drain region, as shown in FIG. 20, and the transistor is operated in the saturated region. For example, a voltage of 0 V may be applied to the first diffusion layer region 207a and the P type well region 202, +1.8 V to the second diffusion layer region 207b, and +2 to the gate electrode 204. At this time, if no electron is stored in the first memory function part 231a, drain current tends to flow. In the case where electrons are stored in the first memory function part 231a, an inversion layer is hardly formed in the vicinity of the first memory function part 231a, and so the drain current does not tend to flow. Therefore, detecting the drain current makes it possible to read information stored in the first memory function part 231a. Here, whether or not electric charges are stored in the second memory function part 231b does not affect the drain current due to the pinchoff in the vicinity of the drain.

In the case of reading information stored in the second memory function part 231b, the second diffusion layer region 207b is set to be a source region, and the first diffusion layer region 207a is set to be a drain region, and the transistor is operated in the saturated region. For example, a voltage of 0 V may be applied to the second diffusion layer region 207b and the p type well region 202, +1.8 V to the first diffusion layer region 207a, and +2 V to the gate electrode 204. Thus, by reversing the source and drain regions in the case of reading information stored in the first memory function part 231a, information stored in the second memory function part 62 is read.

It is noted that if there is a channel region not covered with the gate electrode 204, the presence or absence of excessive electrons in the memory function parts 231a, 231b eliminates or forms the inversion layer in the channel region not covered with the gate electrode 204, as a result of which large hysteresis (change of threshold) may be obtained. However, if the width of the offset region is too large, the drain current is drastically reduced, thereby causing considerable reduction of a read speed. Therefore, it is preferable to determine the width of the offset region so as to enable obtainment of sufficient hysteresis and read speed.

When the diffusion layer regions 207a, 207b reached the edge of the gate electrode 204, that is, when the diffusion layer regions 207a, 207b and the gate electrode 204 were overlapped, the write operation caused almost no change to a threshold of the transistor, though parasitic resistance at the edge of the source/drain regions suffers considerable change (by one digit or more), resulting in remarkable reduction of the drain current (one digit or more). This indicates that detection of the drain current enables read operations and that the transistor provides a function as a memory. However, if a larger memory hysteresis effect is required, it is preferable that the diffusion layer regions 207a, 207b and the gate electrode 204 are not overlapped with each other.

In the above-stated operation method, selective write and erase operations of 2-bit information per transistor become possible. Also, by arraying the storage devices with word lines WL connected to the gate electrodes 204 of the storage devices, with bit lines BL1 connected to the first diffusion layer regions 207a, with bit lines BL2 connected to the second diffusion layer regions 207b, a memory cell array is constituted.

Further in the above erase operation, writing and erasing of 2-bit information per transistor are achieved by reversing the source region and the drain region. However, the storage device may be operated as a 1-bit memory with the source and drain regions being fixed. In such a case, it becomes possible to set the voltage of one of the source/drain regions as a common fixed voltage, which makes it possible to reduce the number of bit lines connected to the source/drain regions by half.

According to the storage device of the present embodiment, as is apparent from the above description, the memory function parts 231a, 231b are formed on both sides of the gate electrode 204, independently of the gate insulating film 203. This makes it possible to execute two-bit operations. Further, since the memory function parts 231a, 231b are separated by the gate electrode 204, interference during rewrite operations is effectively controlled. Also, since the memory function parts 231a, 231b are separated by the gate electrode 204, it is possible to decrease the thickness of the gate insulating film 203 to thereby restrain the short channel effect. Consequently, it becomes possible to miniaturize the device.

### Embodiment 9

This Embodiment 9 relates to changes of electrical characteristics when a rewrite operation is performed in the storage device of the present invention.

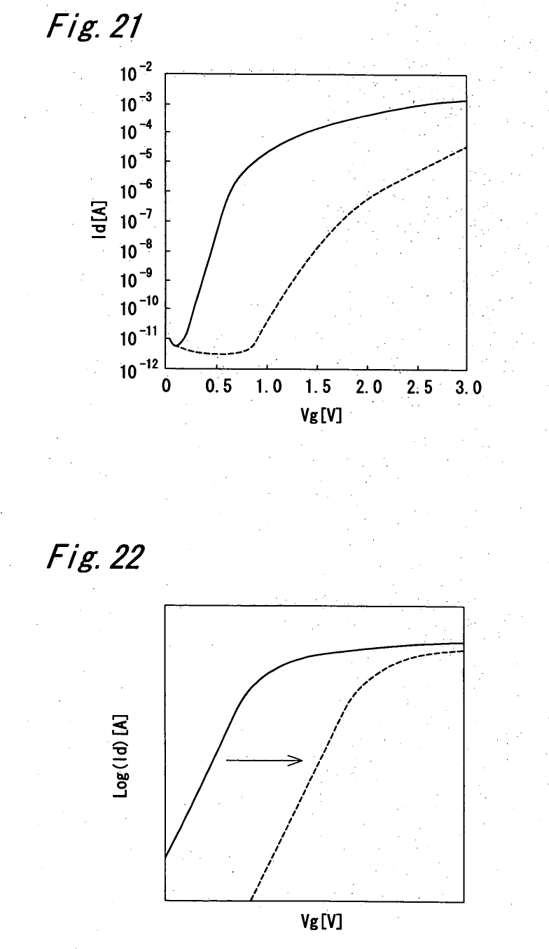

FIG. 21 shows characteristics of a drain current, Id, vs. a gate voltage, Vg, (measured values) when the electric charge amount in the memory function part of an N-channel type memory device changes. In FIG. 21, a solid line curve indicates a relation between the drain current, Id, and the gate voltage, Vg, in an erased state and a dotted line curve indicates a relation between the drain current, Id, and the gate voltage, Vg, in a programmed or written state.

As clearly shown in FIG. 21, when a write operation is performed in the erased state (a state indicated by the solid line), not only the threshold value simply rises, but a slope of the graph dramatically decreases especially in a sub-threshold region. Therefore, even in a region with relatively high gate voltage (Vg), a ratio of a drain current in the erased state to a drain current in the written state is large. For example, at the point of Vg=2.5V, the current ratio is still two digits or more. This characteristic is largely different from that in the case of an EEPROM (FIG. 22). In FIG. 22, a solid line curve indicates a relation between a logarithm of the drain current, Log(Id), and the gate voltage, Vg, in an erased state and a dotted line curve indicates a relation between a logarithm of the drain current, Log(Id), and the gate voltage, Vg, in a programmed, or written state.

The emergence of the above characteristics is a phenomenon peculiar to the case where the gate electrode and the diffusion regions are offset from each other and therefore the gate electric fields hardly reach the offset regions. When a storage device is in the written state, it is extremely difficult for an inversion layer to be generated in the offset region below the memory function part even if a positive voltage is applied to the gate electrode. This causes the small slope of the Id-Vg curve line in the sub-threshold region in the written state as shown in FIG. 21. When the storage device is in the erased state, high-density electrons are induced in the offset region. Further, while a voltage of 0 V is applied to the gate electrode (i.e., in an OFF state), electrons are not induced in the channel below the gate electrode (so that an off current is small). This causes a large slope of the Id-Vg curve line in the sub-threshold region in the erased state and a large increase rate of current (conductance) even in an over-threshold region.

As is clear from the above description, the storage device of the present invention makes it possible to make the drain current ratio of the erased state to the written state particularly large.

The following description discusses examples of an IC card having the storage devices as defined in Embodiments 1 to 7.

### Embodiment 10

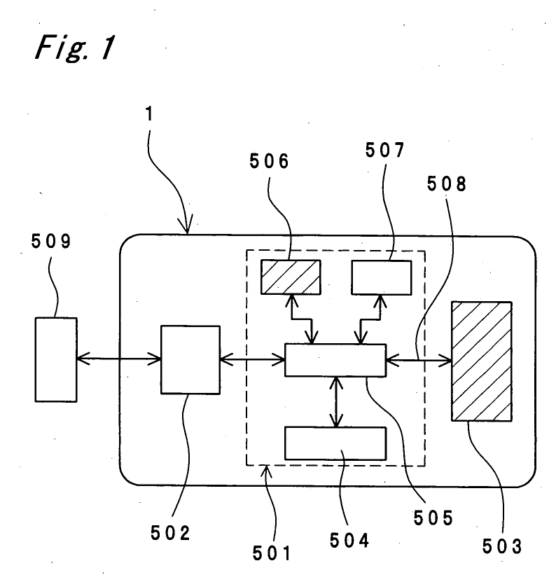

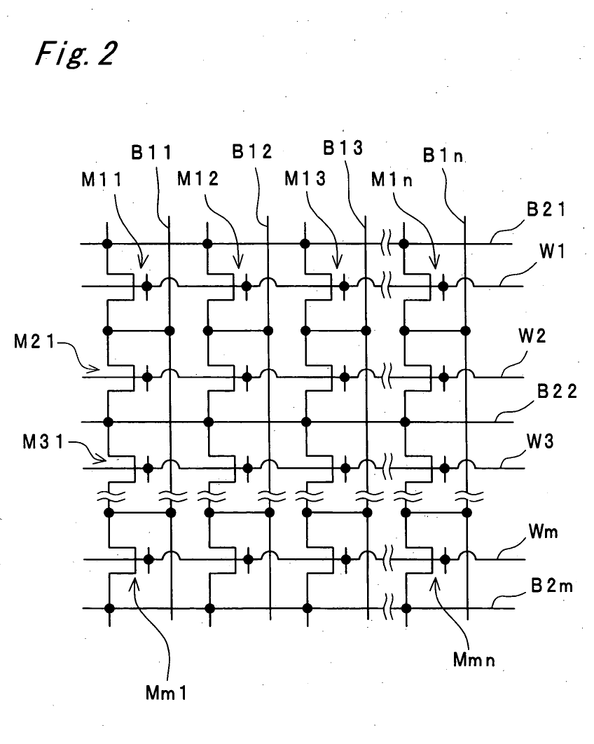

An IC card of Embodiment 10 will be described with reference to FIG. 1 and FIG. 2. FIG. 1 is a view showing the structure of the IC card. FIG. 2 is a circuit diagram showing an example of a memory cell array of storage devices for use in the IC card.

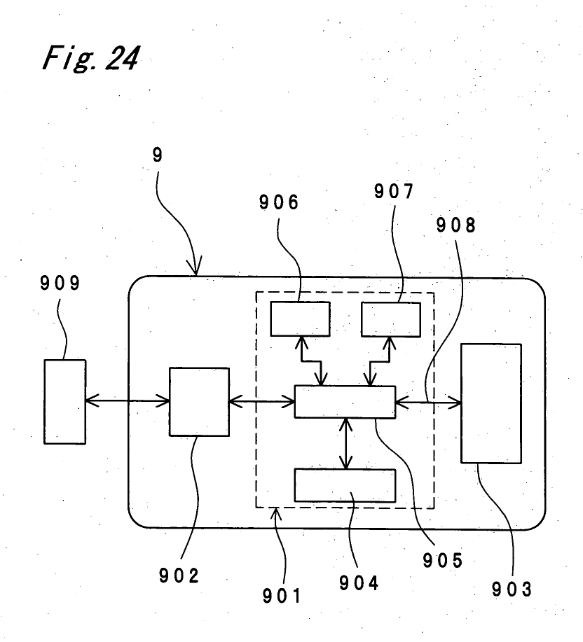

In FIG. 1, there are shown an IC card 1, an MPU 501, a connection portion 502, a data memory portion 503, an operation portion 504, a control portion 505, a ROM 506, a RAM 507, a line 508, and a reader/writer 509. The IC card of Embodiment 10 has a general structure similar to that of the conventional IC card shown in FIG. 24, and therefore description thereof is omitted.

The IC card of Embodiment 10 is different from the conventional IC card of FIG. 24 in the point that in the data memory portion 503, storage devices that allow miniaturization and therefore enable reduction of manufacturing costs, that is, the storage devices according to any of Embodiments 1-7 are used.

In the case where the data memory portion having the storage devices and the logic portion having common logic transistors are incorporated in one chip, an effect of reducing manufacturing costs of the IC card of the present invention becomes still larger since the process for fabricating the storage devices and the ordinary logic transistors in a mixed manner is extremely easy. Following description discusses easiness of the process for fabricating the storage devices and the ordinary logic transistors in a mixed manner.

Each of the storage devices may be formed through the same process as the ordinary logic transistors. As one example, description will be given of the procedure of forming the storage device shown in FIG. 5. First, in a known procedure, a gate insulating film 114 and a gate electrode 117 are formed on a semiconductor substrate 111. Next, on the entire surface of the semiconductor substrate 111, a silicon oxide with a film thickness of 0.8 to 20 nm, more preferably with a film thickness of 3 to 10 nm is formed by thermal oxidation method or deposited by CVD (Chemical Vapor Deposition) method. Next, on the entire surface of the silicon oxide, a silicon nitride with a film thickness of 2 to 15 nm, more preferably with a film thickness of 3 to 10 nm is deposited by CVD method. Further, on the entire surface of the silicon nitride, a silicon oxide with a thickness of 20 to 70 nm is deposited by CVD method.

Next, the silicon oxide, the silicon nitride and the silicon oxide are etched back by anisotropic etching, by which memory function parts optimum for storage are formed on each of the opposite side surfaces of the gate electrode like sidewall spacers.

After that, with the gate electrode 117 and the sidewall spacer-like memory function parts being used as masks, ions are injected so as to form diffusion layer regions (source/drain regions) 112, 113. Then, in a known procedure, a silicide process and an upper interconnect process may be performed.

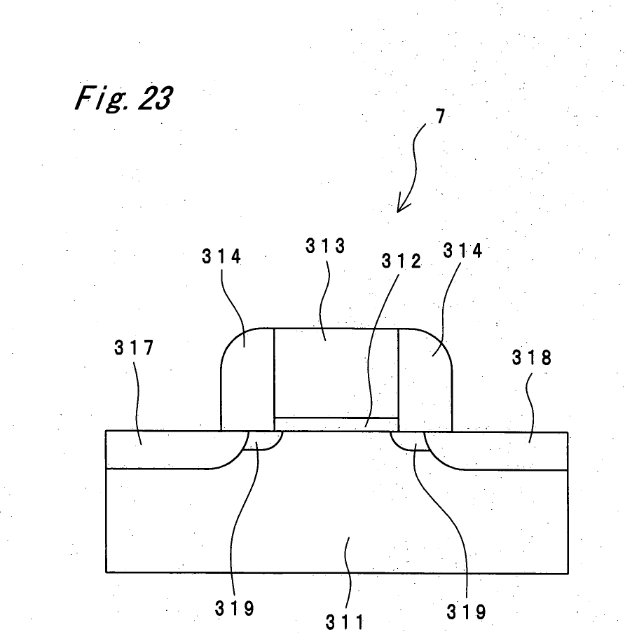

As is clear from the above procedures, the procedure for forming the storage device is extremely high in affinity with the general process for forming standard logic transistors. The transistors that constitutes the standard logic portion generally have the structure shown in FIG. 23. The transistor 7 shown in FIG. 23 is composed of the following components: a semiconductor substrate 311; a gate insulating film 312; a gate electrode 313; sidewall spacers 314 made of an insulating film; a source region 317; a drain region 318; and LDD (Lightly Doped Drain) regions 319. The above structure is close to the structure of the storage device. All what is required for changing the transistor that constitutes the standard logic portion to the storage device is, for example, to impart a function as a memory function part to the sidewall spacers 314 and to remove the LDD regions 319. More specifically, what is required is to change the constitution of the sidewall spacers 314 to the constitution identical to, for example, memory function parts 161, 162 of FIG. 5. Herein, the ratio of the film thickness of the silicon oxides 141, 143 to the film thickness of the silicon nitride 142 is selected such that the storage device adequately operates. Even if the film composition of the sidewall spacers 314 of the transistor 7 that constitutes the standard logic portion is identical to that of the memory function parts 161, 162 of FIG. 5, transistor performance is prevented from being damaged as long as an adequate width of the storage device sidewall spacer (that is, a total film thickness of the silicon oxides 141, 143 and the silicon nitride 142) is selected and the transistor is operated in such a voltage range that does not cause rewrite operations. Also, for placing the transistors that constitute the standard logic portion and the storage devices in a mixed manner, it is further necessary not to form the LDD structure in the storage device portion. For forming the LDD structure, impurities are injected after the gate electrode is formed and before the memory function parts (storage cell sidewall spacers) is formed. Therefore, in injecting impurities for forming the LDD structure, only masking the storage device areas with a photo resist is required, so that the storage devices and the transistors that constitutes the standard logic portion are easily fabricated in a mixed manner. Further, structuring an SRAM from transistors same as those that constitute the standard logic portion enables easy mixed placement of a nonvolatile memory, a logic circuit and an SRAM (Static Random Access Memory).

In the case where it is necessary to apply to the storage device section a voltage higher than a voltage applied to the standard logic portion, all what is required is to add a high pressure-resistant well-forming mask and a high pressure-resistant gate insulating film-forming mask to a standard logic forming mask. The forming process of an EEPROM that is widely used in conventional IC cards is considerably different from that of the standard logic. Consequently, compared to the conventional case where the EEPROM is used as a nonvolatile memory and placed together with the logic circuit, according to the present invention, it becomes possible to dramatically decrease the number of masks and the number of processes. This increases yields of chips in which the logic circuit and the nonvolatile memory are placed together, thereby implementing cost reduction.

According to the storage devices of the present invention, the memory function parts are formed independently of the gate insulating film and placed on both sides of the gate electrode. This enables two-bit operations. Further, since each of the memory function parts is separated by the gate electrode, interference in rewrite operations is effectively restrained. Also, since a memory function implemented by the memory function part and a transistor operation function implemented by the gate insulating film are independent from each other, it becomes possible to make the gate insulating film thinner to control the short channel effect. This facilitates miniaturization of the storage devices.

FIG. 2 is a circuit diagram of one example of a memory cell array structured by arraying the storage devices. In FIG. 2, reference symbol Wm represents an mth word line (thus W1 represents a first word line), B1n represents an nth first bit line, B2m represents an mth second bit line, and Mmn represents a memory cell connected to the mth word line (the mth second bit line) and the nth first bit line. Without being limited to the above configuration, the memory cell array may also be configured such that the first bit lines and the second bit lines are disposed in parallel or that all the second bit lines are connected together into a common source line.

Since the above memory cells are easy to miniaturize and allow two-bit operations, it also becomes possible to reduce an area of the memory cell array in which the storage devices are arrayed. This leads to cost reduction of the memory cell array. Use of this memory cell array in the data memory portion 503 of the IC card enables cost reduction of the IC card.

It is noted that the ROM 506 may be composed of the storage devices. This makes the ROM 506 storing a program for driving the MPU 501 rewritable from the outside, which achieves significant improvement of the functions of the IC card. Since the above storage device is easy to miniaturize and allows two-bit operations, substituting the storage device for the mask ROM hardly causes increase of a chip area. Also, the process for forming the storage device is almost the same as the general CMOS forming process, which facilitates mixed-placing of the storage devices with the logic circuit portion.

Like the storage device shown in FIG. 5 for example, the memory function part of the storage device for use in the IC card of the present invention preferably has a sandwich structure in which a film composed of a first insulator for storing electric charges is sandwiched between a film composed of a second insulator and a film composed of a third insulator. Here, it is particularly preferable that the first insulator is a silicon nitride, and the second and the third insulators are silicon oxides. The storage device having such a memory function part enables high-speed rewrite operations and has high reliability and sufficient holding characteristics. Therefore, using such storage devices in the IC card of the present invention makes it possible to increase the operation speed of the IC card and to improve reliability.

Also, it is preferably to use the storage devices of Embodiment 6 as the storage devices for use in the IC card of the present invention. More specifically, it is preferable that a thickness (T1) of an insulating film that separates a charge holding film (silicon nitride 142) and the channel region or the well region is smaller than a thickness (T2) of the gate insulating film and equal to or more than 0.8 nm. A write operation or erase operation of such a storage device is executed at low voltage, or the write operation or the erase operation is executed at high speed. Further, a memory effect of the storage device is large. Therefore, using such a storage device in the IC card of the present invention makes it possible to decrease the supply voltage of the IC card or to increase the operation speed.

Also, it is preferable to use the storage devices of Embodiment 7 in the IC card of the present invention. More specifically, it is preferable that a thickness (T1) of an insulating film that separates a charge holding film (silicon nitride 142) and the channel region or the well region is larger than a thickness (T2) of the gate insulating film and equal to or less than 20 nm. Such a storage device is capable of improving holding characteristics without intensifying the short channel effect of the storage device, which makes it possible to obtain sufficient memory holding capability while high integration being made. Therefore, using such a storage device in the IC card of the present invention makes it possible to increase storage capacity of the data memory portion so as to improve its functions or to reduce manufacturing costs thereof.

Also, the storage devices for use in the IC card of the present invention are preferably structured such that, as described in Embodiment 1, the regions (silicon nitride 142) for holding charges in the memory function parts 161, 162 are each overlapped with the diffusion layer regions 112, 113. Such storage devices are capable of obtaining sufficiently high read speed. Therefore, using such storage devices in the IC card of the present invention makes it possible to increase operating speed of the IC card.

Also, the storage devices for use in the IC card of the present invention are preferably structured such that, as described in Embodiment 1, the memory function part includes a charge holding film that is disposed in approximate parallel with the surface of the gate insulating film. Such a structure enables restraint of memory effect dispersion among the storage devices, so that dispersion of read current may be controlled. Further, characteristic change of the storage device during memory holding may be decreased, and so the memory holding characteristics are improved. Therefore, using such a storage device in the IC card of the present invention makes it possible to improve reliability of the IC card.

Also, the storage device for use in the IC card of the present invention is preferably structured such that, as described in Embodiment 2, that the memory function part includes a charge holding film that is disposed in approximate parallel with the surface of the gate insulating film, and also includes a portion extending in approximate parallel with a lateral surface of the gate electrode. Such a storage device enables high-speed rewrite operations. Therefore, using such a storage device in the IC card of the present invention makes it possible to increase the operation speed of the IC card.

### Embodiment 11

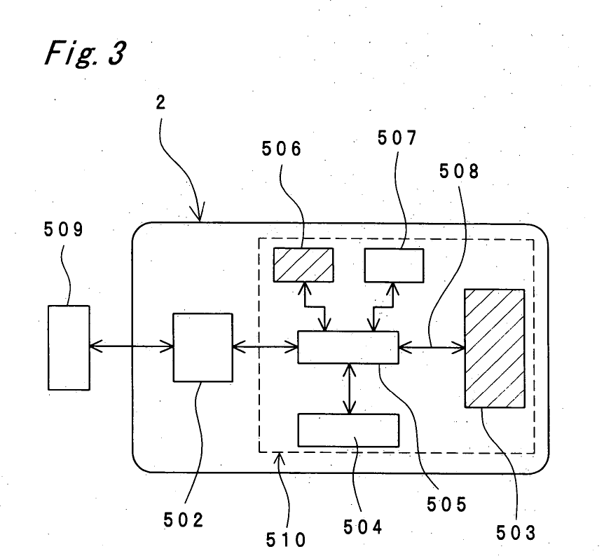

An IC card of Embodiment 11 will be described with reference to FIG. 3.

The structure of the IC card 2 of FIG. 3 is different from the structure of the IC card 1 in that the MPU 501 and the data memory portion 503 are formed in one semiconductor chip so as to constitute an MPU 510 with the data memory portion being incorporated therein.

As already described in connection with Embodiment 1, the forming process of the storage devices that constitute the data memory portion 503 is much alike the forming process of the devices that constitute the logic circuit portion (the operation portion 504 and the control portion 505) of the MPU 510, which enables extremely easy mixed-placing of the devices of both types. If the data memory portion 503 is incorporated in the MPU 510 and both of them are formed on one chip, considerable cost reduction of the IC card becomes possible. Here, using the above-mentioned storage devices in the data memory portion 503 achieves remarkable simplification of the fabrication process, compared with the case of using EEPROMs for example. Therefore, forming the MPU portion and the data memory portion in one chip makes it possible to obtain particularly large cost reduction effect.

It is noted that as with the case of Embodiment 1, the ROM 506 may be structured from the above-mentioned storage devices. This makes it possible to externally rewrite the ROM 506 storing a program for driving the MPU 510, which brings about remarkable increase of the functions of the IC card. Since the above storage device is easy to miniaturize and allows two-bit operations, substituting the storage devices for the mask ROM hardly causes increase of a chip area. Also, the process for forming the storage device is almost the same as the general CMOS forming process, which facilitates mixed-placing of the storage device with the logic circuit portion.

### Embodiment 12

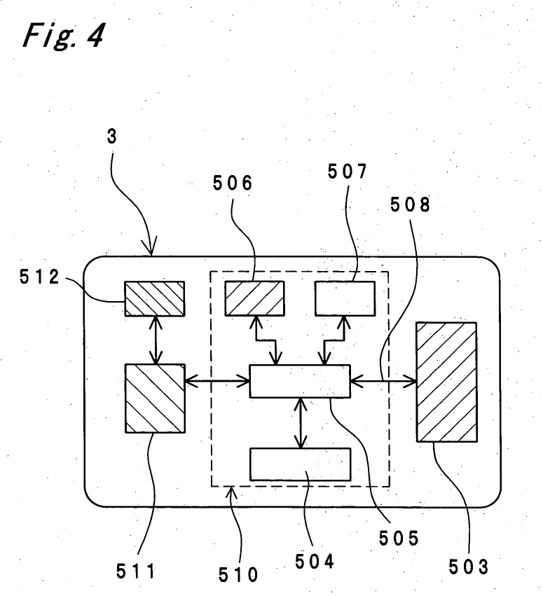

An IC card of Embodiment 12 will be described with reference to FIG. 4.

The IC card 3 of FIG. 4 is different from the IC card 2 in the point that the IC card 3 is of non-contact type. Consequently, the control portion 505 is connected not to the connection portion but to an RF interface portion 511. The RF interface portion 511 is further connected to an antenna portion 512. The antenna portion 512 has functions of communicating with an external apparatus and of collecting current. The RF interface portion 511 has a function of commutating high-frequency signals transmitted from the antenna portion 512 and feeding power, and a function of modulating and demodulating signals. It is noted that the RF interface portion 511 and the antenna portion 512 may be placed together with the MPU 510 in one chip.

Since the IC card 3 of the present embodiment is of non-contact type, it becomes possible to prevent electrostatic destruction through the connection portion. Also, it is not necessarily necessary to have a close contact with an external apparatus, which makes freedom of applications large. In addition, the storage devices constituting the data memory portion 503 each operate at low supply voltage (approx. 9V), compared with conventional EEPROMs (supply voltage of approx. 12V), as described in detail in connection with Embodiment 8, which enables downsizing of the circuit of the RF interface portion 511 and enables cost reduction.

1. An IC card comprising:
a data memory portion (503) having a plurality of storage devices (M11, . . . , Mmn), said data storage devices (M11, . . . , Mmn) each comprising:
a semiconductor substrate (111), a well region (202) provided in a semiconductor substrate, or a semiconductor film (187) disposed on an insulator (188);
a gate insulating film (114, 203) formed on the semiconductor substrate (111), the well region (202) provided in the semiconductor substrate, or the semiconductor film (187) disposed on the insulator (188);
a single gate electrode (117, 204) formed on the gate insulating film (114, 203);
two memory function parts (161, 162, 162a, 231a, 231b) formed on opposite sides of the single gate electrode (117, 204);
a channel region disposed under the single gate electrode (117, 204); and
diffusion layer regions (112, 113, 207a, 207b) disposed on both sides of the channel region, wherein
the storage devices are each structured so as to change a current amount flowing from one of the diffusion layer regions to the other of the diffusion layer regions when voltage is applied to the gate electrode, by an amount of electric charges stored in the memory function parts or by polarization vector.

2. The IC card as defined in claim 1, further comprising:
a logic portion (504).

3. The IC card as defined in claim 2, further comprising:
communication means (502, 512) for communicating with an external apparatus (509); and
collecting means (511) for converting electromagnetic waves applied from outside to electric power.

4. The IC card as defined in claim 2, wherein
the data memory portion (503) and the logic portion (504) are formed in one chip.

5. The IC card as defined in claim 2, wherein
the logic portion (504) includes a storage means (506) for storing a program that defines operation of the logic portion (504),
the storage means (506) is rewritable from outside, and
the storage means (506) includes storage devices having a constitution identical to a constitution of the storage devices (M11, . . . Mmn) of the data memory portion.

6. The IC card as defined in claim 1, wherein
two-bit information is stored in each of the storage devices (M11, . . . Mmn).

7. The IC card as defined in claim 1, wherein
the memory function parts (161, 162, 162a, 231a, 231b) each have a first insulator, a second insulator, and a third insulator,
the memory function parts (161, 162, 162a, 231a, 231b) each have a structure in which a film (142, 142a, 142b) composed of the first insulator having a function of storing electric charges is interposed between the second insulator and the third insulator,
the first insulator is silicon nitride, and
the second and third insulators are silicon oxide.

8. The IC card as defined in claim 7, wherein
a thickness (T1) of a film (141) composed of the second insulator on the channel region is smaller than a thickness (T2) of the gate insulating film (114, 203) and is 0.8 nm or more.

9. The IC card as defined in claim 7, wherein
a thickness (T1) of a film (141) composed of the second insulator on the channel region is larger than a thickness (T2) of the gate insulating film (114, 203) and is 20 nm or less.

10. The IC card as defined in claim 7, wherein
the film (142, 142a, 142b) composed of the first insulator having a function of storing electric charges includes a portion (181) having a surface that is approximately parallel to a surface of the gate insulating film (114, 203).

11. The IC card as defined in claim 10, wherein
the film (142, 142a, 142b) composed of the first insulator having a function of storing electric charges includes a portion (182) extending in a direction approximately parallel to a lateral side of the gate electrode (117, 204).

12. The IC card as defined in claim 1, wherein
at least part of each memory function part (161, 162, 162a, 231a, 231b) is formed so as to overlap the corresponding diffusion layer region.
